(19) United States
(12) Patent Application Publication
(10) Pub. No.: US 2008/0149158 A1
(43) Pub. Date: Jun. 26, 2008

(54) Thermal diodic devices and methods for manufacturing same

(76) Inventors: Mark Logan, Pleasant Valley, NY (US); Frederick A. Flitsch, New Windsor, NY (US); Lloyd Wright, Hopewell Junction, NY (US); Lloyd Young, Pleasant Valley, NY (US)

Correspondence Address: Joseph P. Kincart, Esq., 8153 Middle Fork Way, Jacksonville, FL, 32256, US

(21) Appl. No.: 11/642,327

(22) Filed: Dec. 20, 2006

(51) Int. Cl. H01L 35/28

(52) U.S. Cl. 136/203

(57) ABSTRACT

The present invention provides thermal transfer devices and methods for manufacturing such devices.

### CROSS REFERENCE TO RELATED APPLICATIONS

This application claims priority to the Provisional Application Ser. No. 60/751,712, filed Dec. 19, 2005 and entitled: “Thermal Diodic Devices and Methods for Manufacturing Same.” The contents of each are relied upon and incorporated herein by reference.

### FIELD OF THE INVENTION

This invention relates generally to thermoelectric devices and specifically to a subclass of those devices with thermal diodic characteristics. This character is defined by the ability of the device under electrical influence to transport heat in a particular direction and then to significantly resist the natural thermal diffusion back across the device in the opposite direction. In particular, the present invention provides methods of manufacture and specific unique devices that have thermal diodic character.

As semiconductor integrated circuit speeds and transistor density increases, the need for high efficiency cooling of these devices increases. Furthermore, it is beneficial from a space standpoint to have direct, point of use cooling on these devices to minimize the size and cost of the computer system using these devices. Thermoelectric devices, utilizing the Peltier effect, have been used in this application, but their poor cooling efficiency has prevented their widespread adoption. Parasitic conduction of heat through present thermoelectric materials causes the poor cooling efficiency of current thermoelectric devices. If there were a means of reducing this parasitic thermal conduction, then the Peltier effect can be used with utility to remove heat from high-density semiconductor integrated circuits. The present invention addresses the reduction of this parasitic thermal conduction through the use of novel “thermal diodes” that may be used as thermionic cooling devices on their own, or may be used in conjunction with a Peltier effect thermoelectric device or another type of thermionic emission device to provide point of use cooling to semiconductor integrated circuits.

### DESCRIPTION OF THE DRAWINGS

FIGS. 1A-M illustrate the structure of an ionic conductor type of device as it is processed by the general methods of the present invention.

FIGS. 2, 2A illustrate the general features of an example embodiment of the ionic conductor type of device formed using the concepts of the present invention.

FIGS. 3, 3A illustrate some alternative embodiments of the general example of FIGS. 2, 2A.

FIGS. 4A-M illustrate the structure of a selectively removable gap type of device as it is processed by the general methods of the present invention.

FIGS. 5A-C illustrate the general features of alternative example embodiments of the removable gap type of device formed using the concepts of the present invention.

FIGS. 6A,B illustrate examples of how embodiments of the two types of devices might look when processed into a finished module.

FIG. 7 illustrates example shapes for the insulating gaps of the devices.

FIG. 8 illustrates an example of fully completed embodiments of devices according to the present invention, attached to a semiconductor device.

### DETAILED DESCRIPTION

Overview

The present invention provides thermoelectric/thermionic emission devices with thermal diodic characteristics thereby providing an efficient means of transferring thermal energy from a first area to a second area. As referred to herein, a thermoelectric device includes any device that can controllably transfer thermal energy from one portion of the device to another portion of the device in response to the application of a DC voltage. In addition, some thermoelectric devices include the ability to generate a current in response to a temperature differential applied across different portions of the device. Some examples of thermoelectric devices include Peltier Crystals, which are made up of dissimilar materials. As used herein, a thermal diode includes a device capable of controllably transferring thermal energy in one direction from one portion of the device to another portion of the device and to resist the transfer of thermal energy in the opposing direction.

As presented herein, various embodiments of the present invention will be described followed by some specific examples of various components of the devices presented herein and examples of how the various components may be combined.

### Thermal Energy Devices and Methods of Manufacture

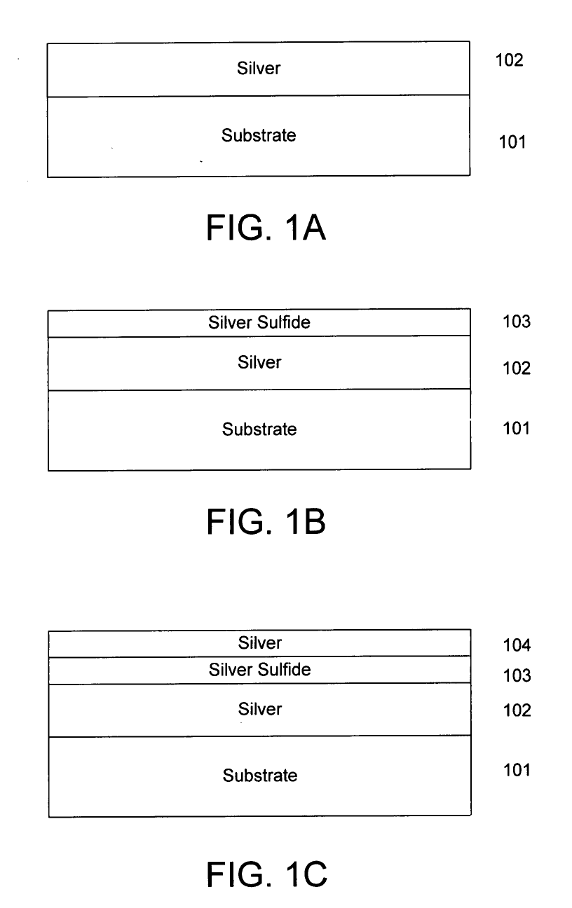

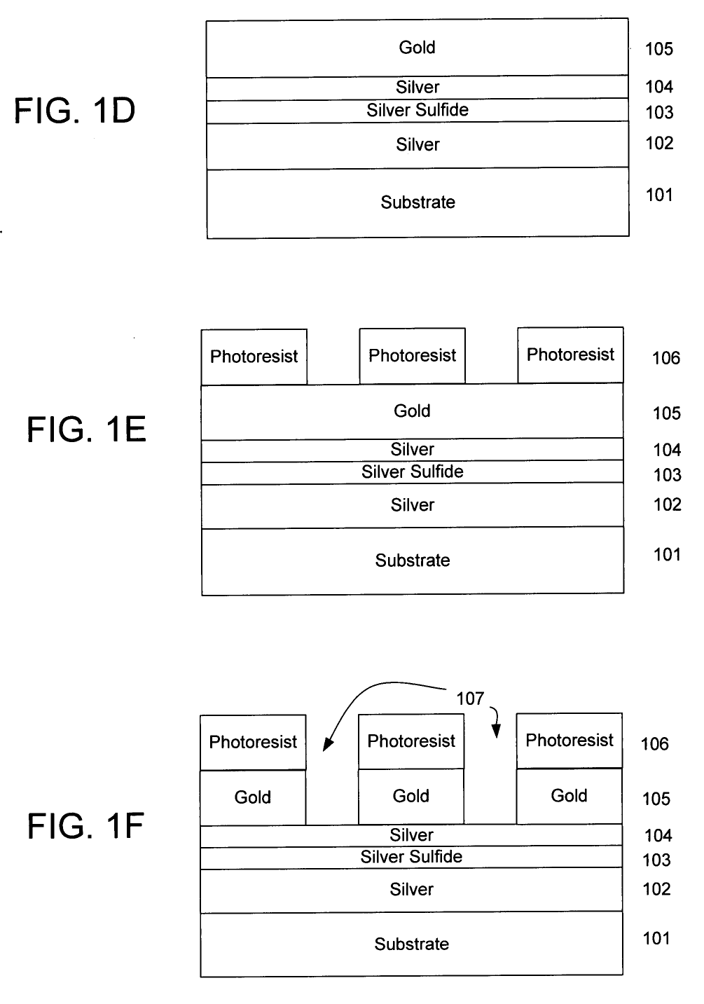

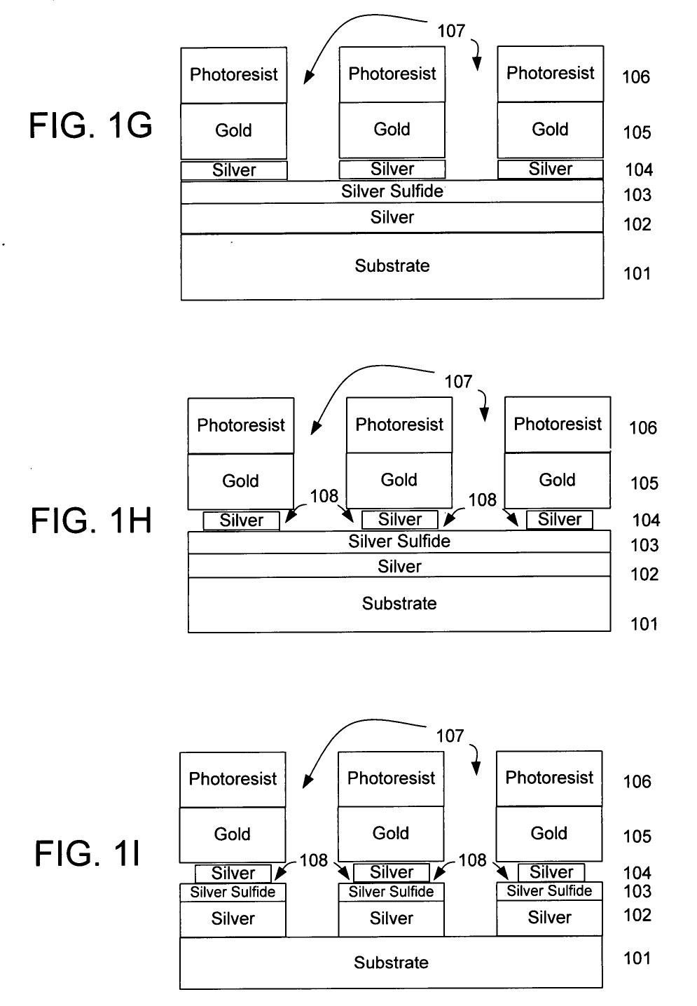

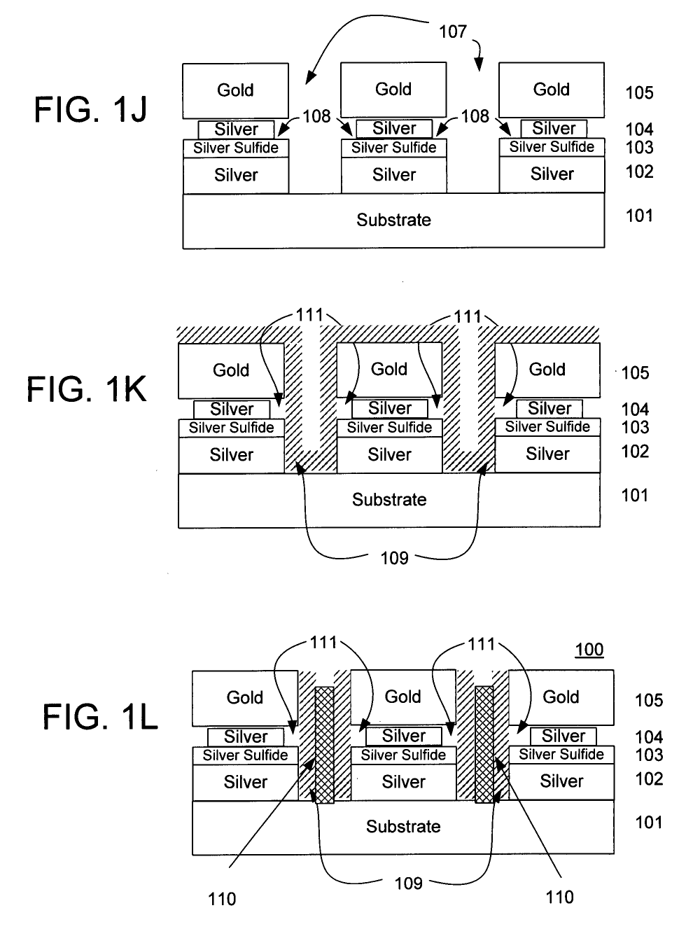

Referring now to FIG. 1, a block diagram depicting some devices according to the present invention and method steps that can be used to fashion devices according to some embodiments of the present invention are illustrated. At 1A, a metallic layer, such as, for example, a layer of Ag 102 can be applied to a metallic or metallic coated substrate 101. The metallic or metallic coated substrate 101 can include, for example, flat quartz with an Au coating or a planarized copper substrate.

In some exemplary embodiments, thickness of the metallic coated substrate 101 can include a substrate greater than, or approximately equal to 100 microns. Generally, embodiments can include any metallic or metallic coated substrate comprising sufficient electrical, mechanical and thermal characteristics. The layer of Ag 102 can be deposited on the metallic coated substrate 101, for example via sputter deposition or plating. In other embodiments, an Au plate can take the place of the metallic coated substrate with an Au coating.

At 1B, the Ag layer 102 can be reacted to form a conductive ionic layer 103, such as for example, silver sulfide (AgS). The ionic conductive layer 103 can be formed, for example by reacting the Ag 102 in a sulfide inducing environment, such as, for example, exposure to H₂S at 80° C. In some embodiments, the thickness of the AgS layer 103 may be self limiting by the environment in which it is created. Some embodiments may include an AgS layer 103 of 80 Ang to 120 Ang.

At 1C, a second metallic layer 104, such as a second layer of Ag 104 can be applied on top of the conductive ionic layer 103, such as, the layer of Ag₂S layer 103. The second metallic layer 104 can be applied by any method known in the arts. In some embodiments, for example, the second layer of Ag 104 can be deposited via sputtering or applied via evaporator plating.

For generality, it should be apparent to those skilled in the arts that the combinate of 102, 103 and 104, which has been described as Ag, Ag₂S, and Ag, can be formed by an equivalent combination of layers that would constitute a layer formation with an ionic conductor in the middle. Said middle layer, 103, can be chemically formed, as was the case with Ag₂S, or it can be separately deposited.

At ID, a third metallic layer 105, different than the second metallic layer 104 can also be deposited. In some embodiments, the third metallic layer 105 can include gold (Au). The Au layer 105 can be deposited by any known means, such as, for example, via sputter or evaporator plating.

Although this embodiment would describe layer 105, as different from the constituents of layer 104, for generality it should be noted that the presence of an interface layer between like metal layers 104 and 105 (if 104 and 105 were the same metals) can provide a sufficient formation for the device processing flow described in this invention.

Referring now to FIG. 1E, after the Au layer 105 has been applied, portions of the applied layers 102-105 can be selectively removed. At 1E, a photoresist pattern can be applied as a photoresist mask 106 on top of the layer of Au 105. The pattern can be applied by any known method in the arts. In some preferred embodiments, the pattern will include the basis of at least one discrete device and in some embodiments, the basis of multiple discrete devices. In some embodiments, discrete devices can be fashioned in a shape which corresponds with the physical characteristics of a particular application. For example, some embodiments can include a photoresist pattern with multiple shapes, each shape corresponding with the physical dimensions of a computer chip that the thermal diodic discrete device will be utilized to cool, other shapes may include circular or semi-circular shapes, octagons, pentagons, rectangles or any other desired shape. For the purposes of this description, a simple rectangle will continue to be described, however, this is not meant to limit the scope of the invention.

In some preferred embodiments, the photoresist mask will define multiple discrete devices. A gap 107, shown in its initial stages of formation in Fig. IF, can separate each device. For example, the gap 107 may be between 1,000 Ang to 10,000 Ang, but in general, the gap is only limited by the physical dimensions of the materials being used, such as, for example, the physical size of the metallic substrate 101, the design of the pattern and the number of devices defined.

At 1F, etching can be used to remove portions of the third metallic layer 105 left exposed by the photoresist mask 106. In the example illustrated, the third metallic layer 105 includes Au. Etching can be accomplished using any method known in the art, such as, for example, reactive ion etching or sputter/physical bombardment etching. In some embodiments, anisotropic etching can be utilized to etch one or more layers 102-105 in a pattern closely defined to the pattern defined by the photoresist mask 106. In other, less preferred, embodiments the etching can be performed by isotropic chemical etching techniques.

At 1G, etching can be additionally used to remove portions of layer 104 based on the pattern of the photomask. In the preferred embodiment shown, as found in FIG. 1H, a recess in the shape of the feature formed by etching of layer 104 can be formed by use of an isotropic chemical etching process. Such processing would result in a recess of the profile of the gap 107 at all edges of the remaining feature from layer 104. This recess is indicated as 108. At 1J, etching can be additionally used to remove defined portions of one or more of: the second metallic layer 104, the conductive ionic layer 103, and the first metallic layer 102. Accordingly, in some embodiments, anisotropic etching can be continued resulting in essentially a uniform cut through all of the layers 102-105 until the metallic coated substrate 101 is reached.

In some other embodiments, isotropic etching can be used to remove portions of one or more of: the second metallic layer 104; the conductive ionic layer 103; and the first metallic layer 102; thereby defining an undercut region 108 beneath the third metallic layer 105. Therefore, following the examples above, some embodiments can include use of an etching technique, such as selective wet chemistry etching, to remove portions of the second layer of silver 104, the silver sulfide 103 and the first layer of silver 102 underneath layer of gold 105, thereby creating an optional undercut 108 under the gold 105.

In addition, it should be understood that embodiments can include undercut regions 108 or not include the undercut regions 108.

Referring again to FIG. 1, at 1K, following the etching steps, the photo resist pattern 106 is removed. In some embodiments, such removal may be performed by a standard chemical processes used in the art to strip photoresist or a chemical plasma etching tool, typically referred to as an asher. Additional processing, such as, for example, additional wet cleaning processing, can result in a clean structure including primarily the materials of layers 101-105.

At 1L an insulator 109 can be applied into the etched out areas 107. In some embodiments, in which the etching created an undercut 108 under the gold 105, the insulator layer 109 can be applied into the etched out areas 107, but leave a void 111 in the undercut region. Other embodiments can include the insulator 109 filling the undercut region 108. In still other embodiments, no undercut region 108 will be formed by the etching and the insulator layer 109 only fills the etched out areas 107.

In some other embodiments, the undercut region 108 is evacuated and encapsulated with deposited insulator layers. A common deposition process for insulators, PECVD, can carry out this effect since the process is inherently a vacuum based process. Therefore, the ambient in the encapsulated void region, 111, reflects the pressure in the deposition process and any gas materials present in that deposition ambient. For example, in some embodiments, the undercut region 108 can be filled with nitrogen and sealed in with an insulator layer 109 such as Silicon Oxide. In other embodiments, the undercut region 108 can contain other gasses. In the preferred embodiment, the nature of the ambient of the undercut region 108, may be less critical than for other embodiments, where the undercut 108 occurs along all layers 102-104.

The layer thickness of insulator layer 109 can be made thick enough to entirely fill the gap 107. However in the preferred embodiment, its thickness would be less than that to fill the gap. Such a strategy can allow for the gap to be completed with a material composition that would have lower thermal transfer capabilities than the material of the insulator 109, since such thermal transfer would be a parasitic aspect of the device thus formed. Nevertheless, the layer formed in etched out areas 107, can be formed in such a manner to ensure mechanical rigidness of the formed layer structure. It can also provide significant sealing ability of the layer structure from the ambient.

At 1L, a PECVD process used to form layer 109 would result in deposition filling along the sides of the gap 107 as well as at the bottom of the gap 107. Furthermore, the top metal structure 105, would also be coated with the deposited insulator 109 as illustrated. In some embodiments this coating 109 can be removed with an etching step that would etch the flat surfaces of the insulator 109-110, and, in some embodiments, also etch the tops of metal structures 105 and the bottom of the gaps 107, leaving vertical structure along the sidewall of the gap 107.

In some embodiments, including a preferred embodiment, an additional layer of insulator 110 can include a low density oxide or a low thermal conducting material. For example, a layer of low density SiO₂ can be processed by spinning the material onto the substrate. Such a spin on glass (SOG) material would fill the portion of the gap 107 that was not filled in initially with the insulator 109. This SOG would preferentially fill this gap, but can end up with some additional deposit on top of the gold. An etching process, either dry or wet can once again be used to remove the insulator from the top of the Au layer 105. Alternatively, if the initial insulator layer 109 was not etched as described above, some embodiments can include composite insulator layers 109 and 110 being etched by reactive ion etching. Embodiments can therefore result in a structure 100 that is generally equivalent to that shown in FIG. 1M.

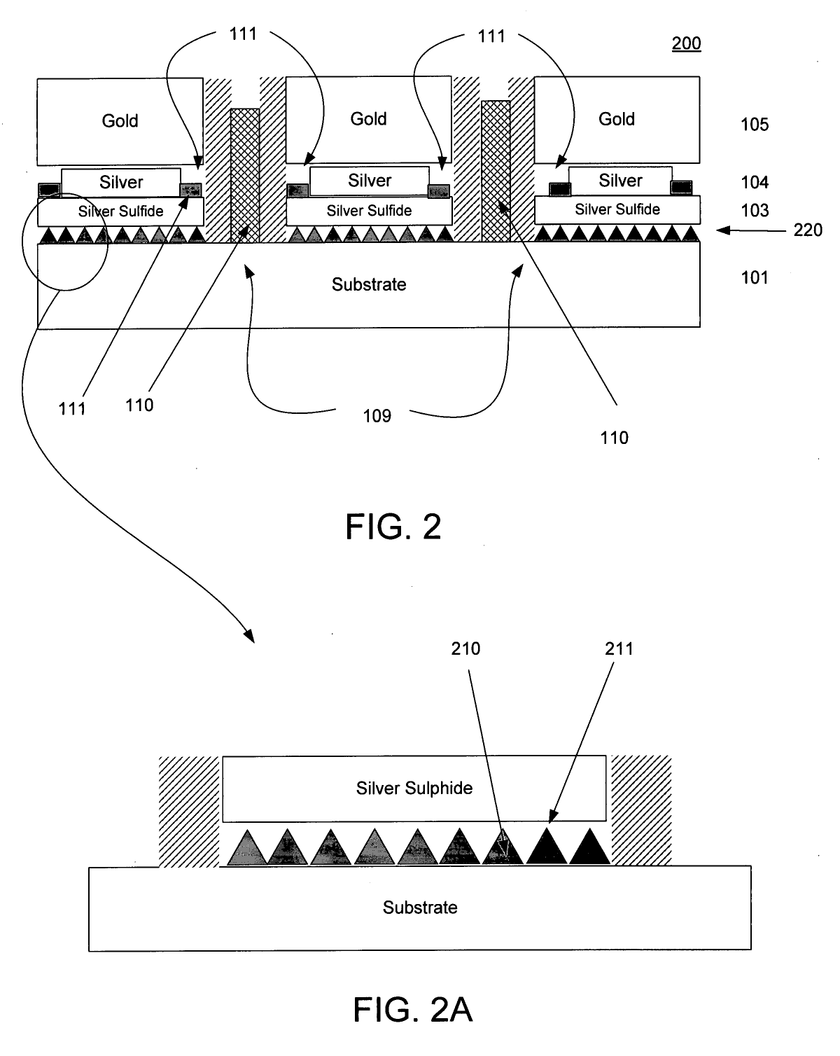

Referring now to FIG. 2, after the device structure 200 has been thus formed, the structure 200 can be further processed by applying an electrical current by various means across the layers from the gold 105 to the substrate 101. In devices of the types that include an ionic conductor layer in them, as shown in the preferred embodiment as layer 103, an electrical current can be passed through the ionic conductive layer 103 to cause two forms of electrical motion occur. Electrons can flow from one side of the device to the other, for reference we will consider the case where electrons flow from Au 105 to the substrate 101. In such embodiments, there will also be a contribution to the current that comes from the motion of positively charged silver ions inside the ionic conductor 103 in a direction opposite to the electron flow. Such a flow will result in silver atoms being depleted from the interface of layer 103 with layer 102.

In FIG. 2, the effect of the current applied from the Au 105 to the substrate 101 on the overall device 101-105, 109-111 of these types, is generally illustrated. As can be seen, the Ag layer 102 has been has been physically altered into a new layer indicated as layer 220.

Referring now to the close up diagram shown in FIG. 2A, a rough surface topography that would result from the atomic movement is generally illustrated and indicates “Spike like” features 210 which are formed from the silver material and also a gap, shown as 211. The gap 211 is formed as a result of silver atoms that move under the influence of the field across the device 200 until a last silver atom moves and there is no longer a solid connection across the Au layer 102.

With the formation of a gap 220 in the silver layer 102, the structure of the device 200 in other ways remains the same. The Au 105 and the AgS layer 103 continue to be held in place by the other layers of the resulting device, such as, for example, the layers of insulator 109 and SOG 110. In addition, with the layer of Ag 102 removed, the resulting gap 211 acts as a thermal insulator.

In some embodiments, solid state conduction of electrons across the Ag layer 102 ceases with the formation of the gap 211. Any current which flows with the gap 211 comes from different forms of conduction, such as, for example, tunneling of electrons across the gap 211. This structure 200 provides a desired form which enables control of thermionic effects across the gap 211 and also has insulating properties due to the gap 211. Some embodiments of the present invention can include further processing of the environment of the gap 211, however FIG. 2 shows some embodiments of a device according to the concepts of this invention which includes the desired thermal diodic behavior.

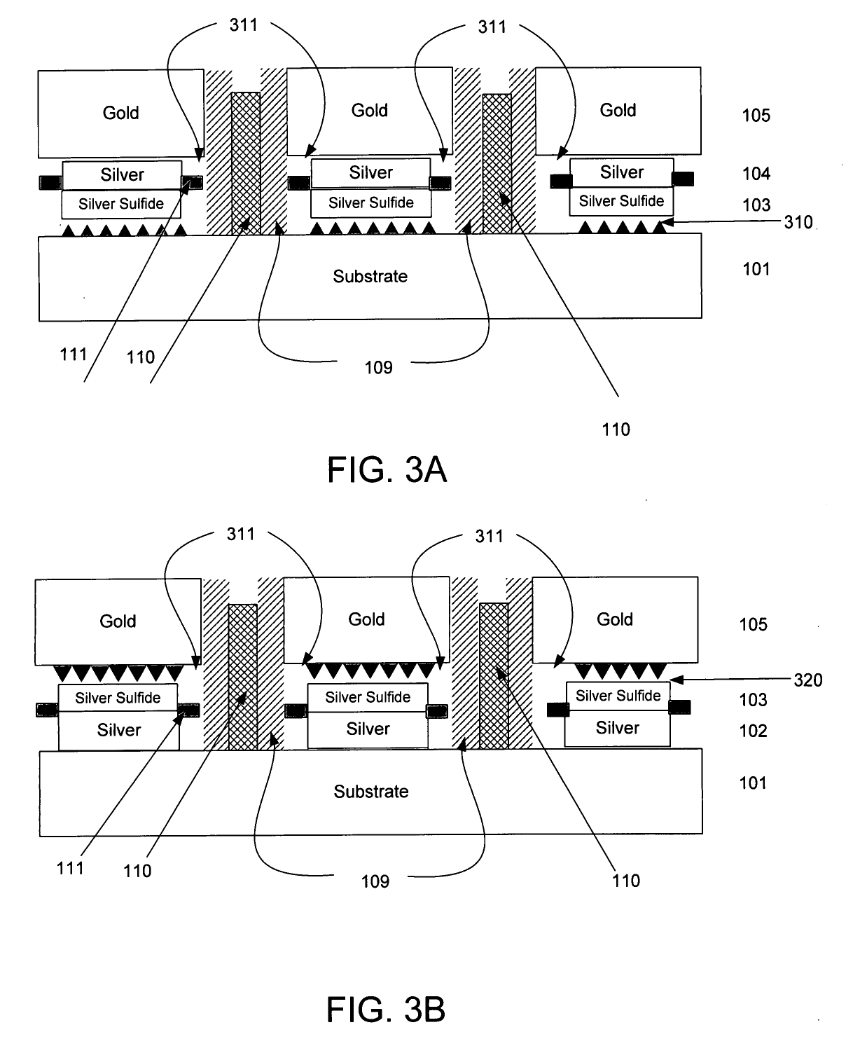

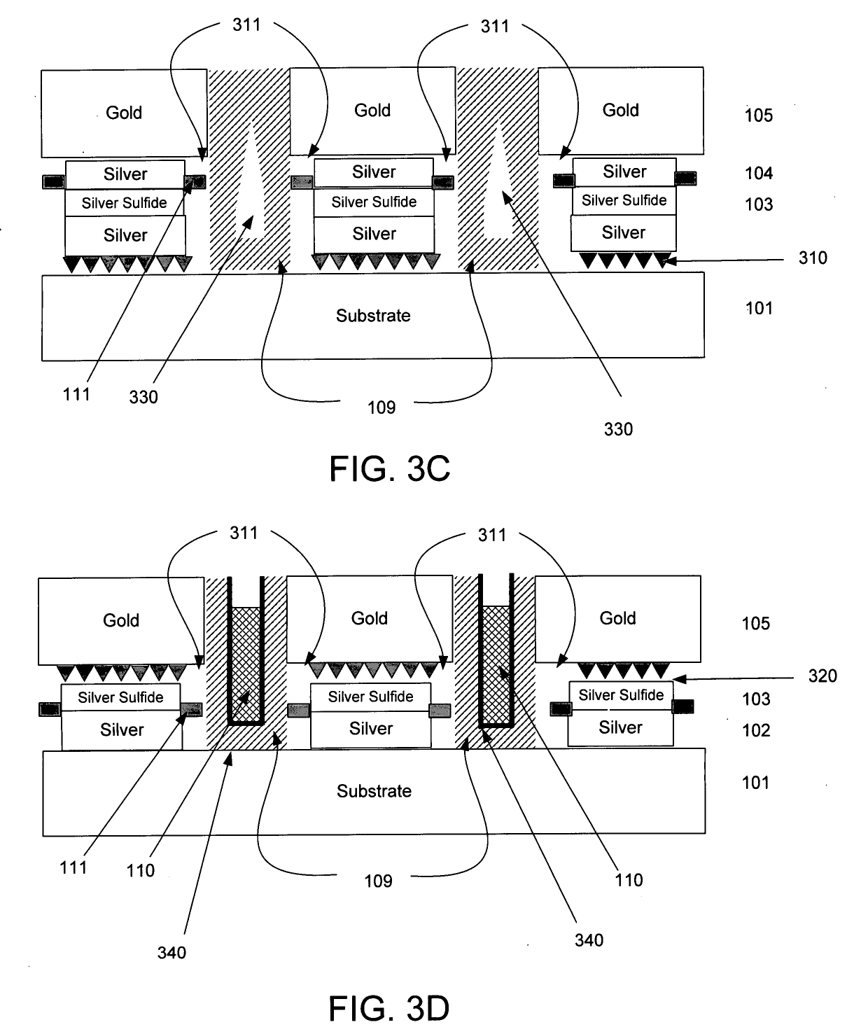

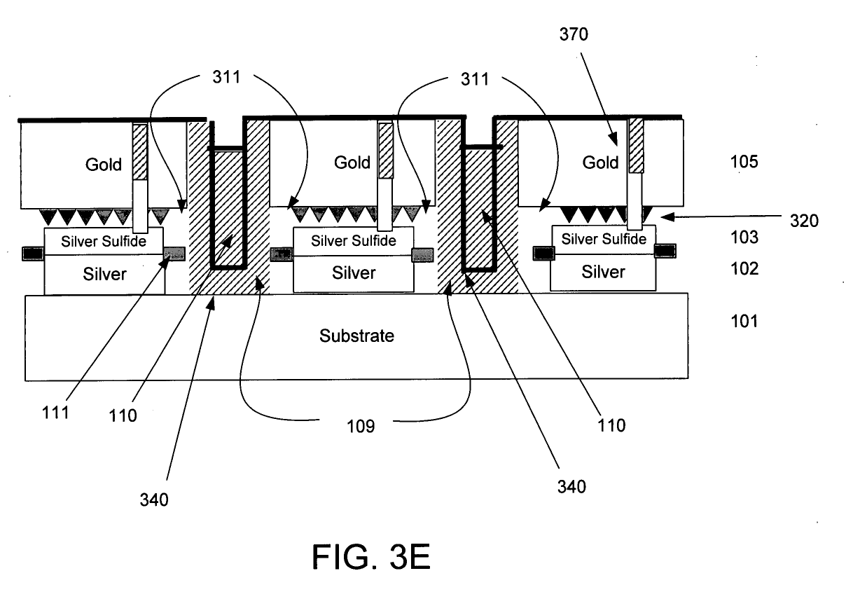

Although the present invention has been presented in several embodiments in this description and the drawings, several other options are also within the scope of the present invention. For example, referring now to FIG. 3A, some alternate embodiments of a device according to the present invention are shown, where the processing step of the undercut region (referred to in previous drawings as 108 and 111) can be performed along the entire length of the device gap 107. In these embodiments, it is possible to flow the electrical current in either direction and have a defined gap where the silver atoms can migrate to.

FIG. 3A, illustrate exemplary embodiments where the electron flow is from 105 towards 101. Furthermore, FIG. 3B illustrates exemplary embodiments with an analogous structure that is formed as a result of electron flow directed from 101 towards 105. An alternative embodiment of the same basic structure is shown in FIG. 3C.

In another aspect, the above embodiments can additionally include a PECVD step to form item 109 which is performed in a manner that it will “neck off” at the top forming void 330. In these embodiments, the gap 310-311, in the shape of a channel, would be filled with a vacuum space and have low thermal conductivity.

Referring now to FIG. 3D, the presence of a vacuum in the region of the created gap, 320, can be important to various embodiments of the device type. In addition, the presence of an insulator 109 comprising PECVD film can form the environment of the gap 320 and undercut region 308 in a low vacuum state. However, in some embodiments, further processing of the device 3B may allow for molecules to penetrate the PECVD film 109 thereby subverting the vacuum state of the gap 310, 320 and the undercut 308. In some embodiments, therefore, a metallic film 340 can be applied by deposition on the outside of the PECVD insulator film 109. The metallic film 340 seals the created gap 320 from molecules that may otherwise penetrate the PECVD film.

A further refinement of the device type is illustrated in FIG. 3E. In addition to the features added for the device in FIG. 3D, FIG. 3E illustrates additional embodiments which contain an access via 370 that is cut into the Au 105. Said access via 370 can be formed by another photomask step that allows a reactive ion etch process to etch a hole into the Au 105. The depth of the access via 370 can be at least as deep as the sulfide layer 103. Such a via hole 370 can allow for access to the formed gap region 310, 320 for various purposes. In some embodiments, the purposes can include evacuation of the gap region 310, 320 and also chemical and gaseous treatment of the surfaces inside the region of various types. It should be noted that the access via 370 feature has been described in relation to the embodiments of FIG. 3E but it should be apparent that a via 370 can as well be more generally applied to various embodiments.

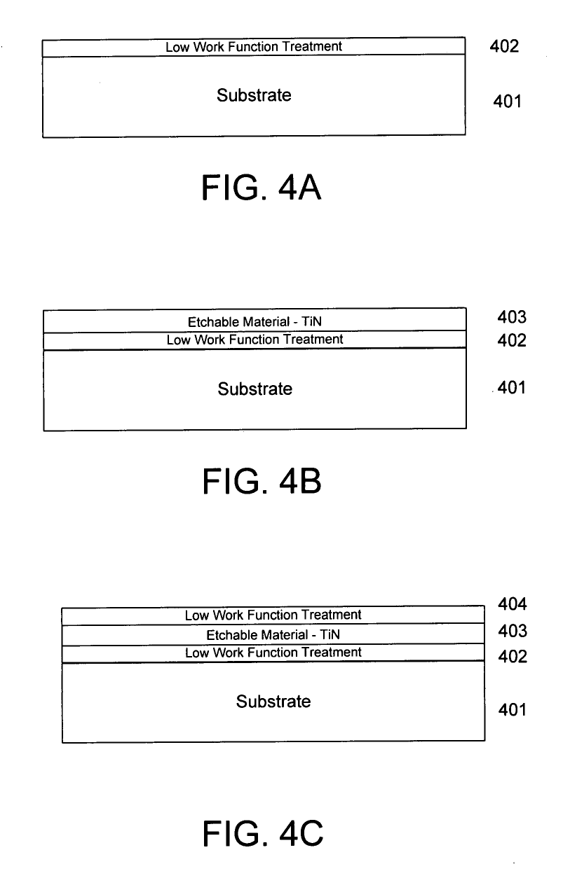

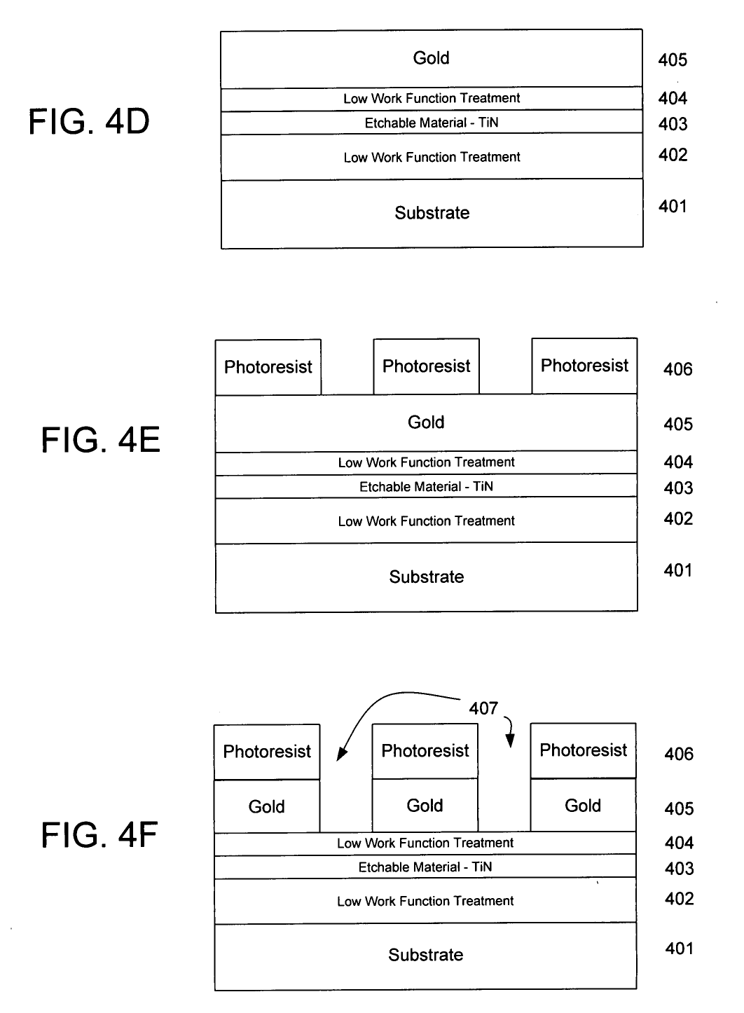

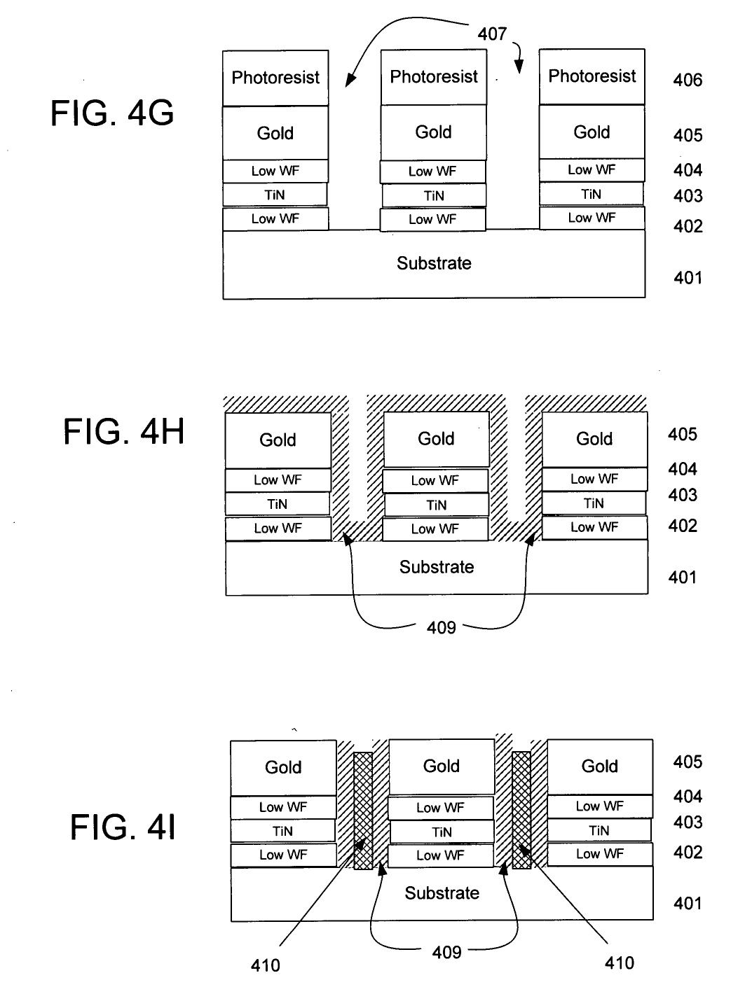

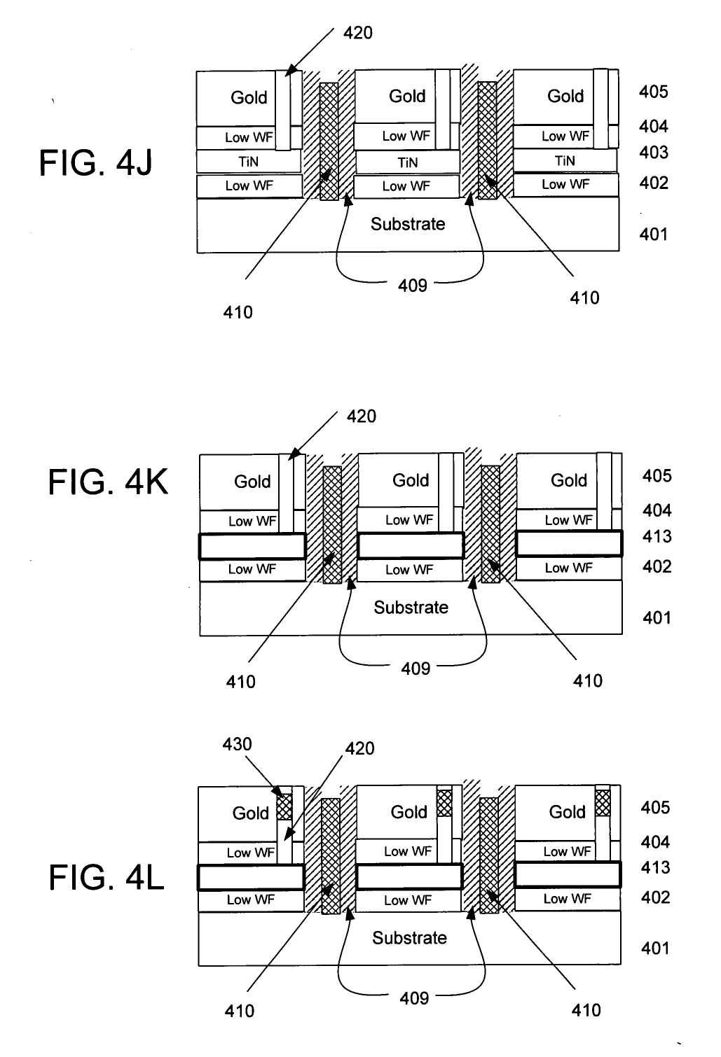

Referring now to FIGS. 4A-4M, in some embodiments of a device formed according to the methods of the present invention, an active region of the device, where tunneling and emission can occur, may be formed in a different general approach. Instead of having a gap formed under the action of an ionic conductor, it can be formed by selective etching of a sacrificial film that is initially formed with a dimension that can be processed into a desired gap. The method for making some possible embodiments of this concept is illustrated in FIGS. 4A through 4M.

At 4A, a metallic layer, such as, for example, a layer of Ag whose surface has been altered to lower its work function, identified as low work function treatment layer 402, can be applied to a metallic or metallic coated substrate 401. Examples of low work function materials include Silver-Oxide-Cesium Φ˜0.8 eV, Cesium, Cs Φ=1.96 eV, Copper-Lithium, CU—Li Φ=2 eV, Calcium Nitride Ca₂N Φ=2.35 eV. The metallic or metallic coated substrate 401 can include, for example, flat quartz with an Au coating or a planarized copper substrate.

In some exemplary embodiments, the thickness of the metallic coated substrate 401 can include a substrate greater than, or approximately equal to 100 microns. Generally, embodiments can include any metallic or metallic coated substrate comprising sufficient electrical, mechanical and thermal characteristics. The layer of Ag 402 can be deposited on the metallic coated substrate 401, for example, via sputter deposition or plating. The Ag is applied in a manner that its top surface can be altered in a manner to make a low work function surface region 402.

At 4B, metallic layer 402 can be coated with a film layer 403 that can be selectively removed at a later step. The options for such a layer can be diverse, including, for example, organic films, and inorganic films. More specifically the coating 403 can include insulators, such as, for example, silicon oxide. In some embodiments, this layer 403 will need to be on the order of the gap dimension, therefore, in such embodiments the film layer 403 must be able to be applied with controllable thicknesses in the regime of 10-100 angstroms, and in some embodiments be applied in a manner that does not change the characteristics of the low work function surface of layer metallic layer 402. For the embodiment illustrated, the film layer 403 has been described as Titanium Nitride (TiN). TiN can be applied by established atomic layer deposition techniques in the desired thickness range. Furthermore, TiN can be etched in a manner that can be selective to the other films described with acidic solutions with dissolved hydrogen peroxide.

At FIG. 4C, a second metallic layer 404, such as a second layer of Ag, the initial stages of which can be treated in a manner to lower its work function, can be applied on top of the etchable film layer 403, such as, a layer of Ag₂S 403. The second metallic layer 404 can be applied by any method known in the arts.

At FIG. 4D, a third metallic layer 405, in some embodiments different than the second metallic layer 404, can also be deposited. In some embodiments, the third metallic layer 405 can include gold (Au). The Au layer 405 can be deposited by any known means, such as, for example, via sputter or evaporator plating.

Although the embodiments generally described herein indicate that the material of layer 405 is different from the material of layer 404, it should be noted that precise control of the thickness of metal layers 404 and 405 can provide a sufficient formation for some subsequent steps in the device processing flow described in this invention, even if 404 and 405 are the same metal.

Referring now to FIG. 4E, after the Au layer 405 has been applied, portions of the applied layers 402-405 can be selectively removed. At 4E, a photoresist pattern can be applied as a photoresist mask 406 on top of the layer of Au 405. The pattern can be applied by any known method in the arts. In some preferred embodiments, the pattern will include the basis of at least one discrete device and in some embodiments, the basis of multiple discrete devices. In some embodiments, discrete devices can be fashioned in a shape which corresponds with the physical characteristics of a particular application. For example, some embodiments can include a photoresist pattern with multiple shapes, each shape corresponding with the physical dimensions of a computer chip that the thermal diodic discrete device will be utilized to cool, other shapes may include circular or semi-circular shapes, octagons, pentagons, rectangles or any other desired shape. For the purposes of this description, a simple rectangle will continue to be described, however, this is not meant to limit the scope of the invention.

In some preferred embodiments, the photoresist mask will define multiple discrete devices. A gap 407, shown in its initial stages of formation in FIG. 4F, can separate each device. For example, the gap 407 may be between 1,000 Ang to 10,000 Ang, but in general, the gap is only limited by the physical dimensions of the materials being used, such as, for example, the physical size of the metallic substrate 401, the design of the pattern and the number of devices defined.

At 4F, etching can be used to remove portions of the third metallic layer 405 left exposed by the photoresist mask 406. In the example illustrated, the third metallic layer 405 includes Au. Etching can be accomplished using any method known in the art, such as, for example, reactive ion etching or sputter/physical bombardment etching. In some embodiments, anisotropic etching can be utilized to etch one or more (FIG. 4G) layers 402-405 in a pattern closely defined to the pattern defined by the photoresist mask 406. In other, less preferred embodiments, the etching can be performed by isotropic chemical etching techniques.

At 4H, following the etching steps, the photo resist pattern 406 is removed. Removal may be performed by standard chemical processes used in the art to strip photoresist or a chemical plasma etching tool, typically referred to as an asher. In some embodiments, additional wet cleaning processing can also be applied to result in a clean structure consisting primarily of the materials of layers 401-405.

At 4H, a PECVD process used to form layer 409 can result in deposition filling along the sides of the gap 407 as well as at the bottom of the gap 407. Furthermore, the top metal structure (as illustrated, gold) 405, would also be coated with the deposited insulator 409. In some embodiments, the insulator layer 409 can be removed with an etching step that would etch the flat surfaces of the insulator 409, including the tops of gold features 405 and the bottom of the gaps 407, leaving vertical structure along the sidewall of the gap 407.

In some embodiments, including the preferred embodiment, an additional layer of insulator 410, such as a low density oxide or a low thermal conducting material, can be applied over the insulator 409. For example, a layer of low density SiO₂ can be processed by spinning the material onto the substrate. In some embodiments, the spin on glass (SOG) material 410 can fill the portion of the gap 407 that was not filled in initially with the insulator 409. Embodiments can also include application of the SOG 410 which results with additional deposit on top of the gold. An etching process, either dry or wet can once again be used to remove the SOG insulator 410 from the top of layer 405. Alternatively, if the initial layer 409 was not etched as described above, some embodiments can include the composite of layers 409 and 410 being etched by reactive ion etching.

At 4J, a device according to the present invention is illustrated following the application of the insulation layers 409 and 410 and etching steps.

At 4K a via hole 420 (or pore) is etched into the top structure 405. The access via 420 can be formed by another photomask step which allows a reactive ion etch process to etch a hole into the gold 405. The depth of the via hole 420 can be at least as deep as the sulfide layer 403. and allow for access to the selectively etchable layer 403. In the present embodiment, the via 420 is shown to stop at or on the TiN layer 403. In practicality the via 420 can be etched even deeper, so long as it contacts the TiN layer 403.

At 4L, the etchable layer 403 is removed and replaced with a gap 413. For example, by introducing mixtures of sulphuric acid and hydrogen peroxide, among other etchant solution possibilities, the TiN layer 403 can be dissolved. Removal of the TiN layer 403 will create a gap 413 with dimensions defined by the original 403 structure. Treatments can also be applied to evacuate the gap 413 through the via 420, thereby leaving a gap 413 with low work function coated surfaces on either side of the gap 413.

At 4M, the structure is shown after a vacuum treatment evacuates the gap region 413 and the via 420. A PECVD Insulator deposition process can next be employed at low vacuum to seal the via near the top of the opening, 430. In any of the CVD processes where a gap portion of a device is sealed up, the actual ambient of the PECVD process may be controlled to contain a predominance of alternative (to the PECVD reactants) non reactive gasses that at the low pressures of the device would have minimal thermal transport characteristics.

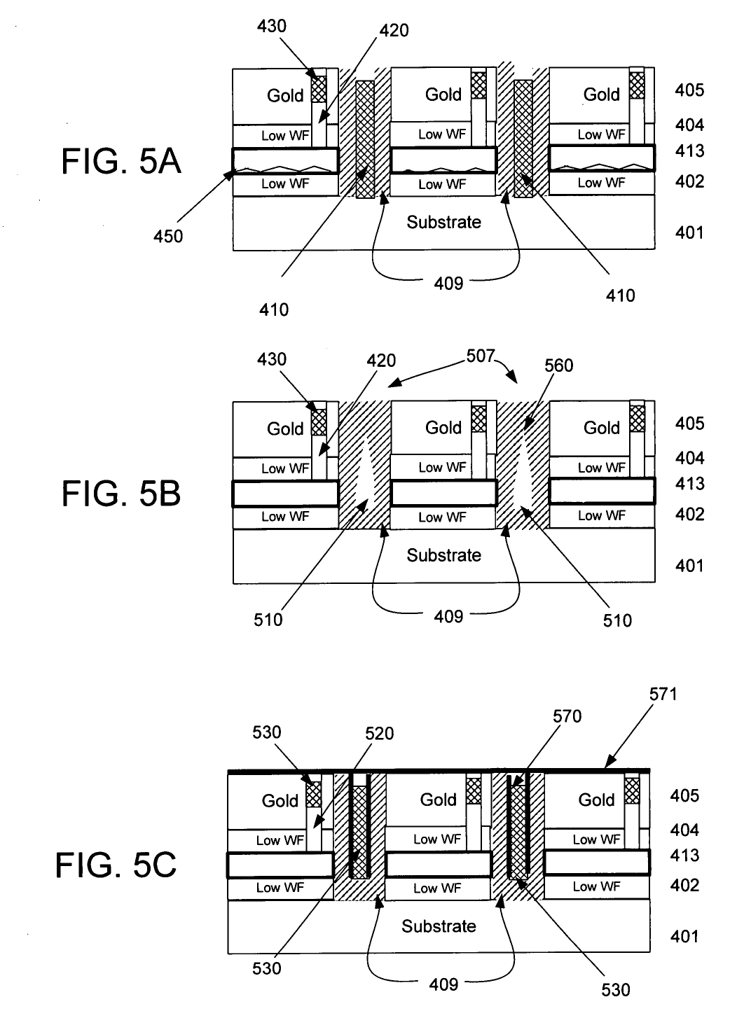

Referring now to FIGS. 5A-5C, although the present invention has been presented in several embodiments in this description and the drawings, several other options and embodiments are also within the scope of the invention. For example, in FIG. 5A the same basic structure has been formed. However, in the initial stages of the steps that were used to form the low work function layer 402, a processing step can be used to intentionally roughen the surface topography 450 of the low work function metal 402. Such a rough topography 450 can be carried out, for example by: etching processes, deposition processes, heat treatments of various forms, or other methods known in the arts.

In FIG. 5B other alternate embodiments of devices and methods according to the present invention is shown. The PECVD step which forms item 409 can be carried on in such a manner that it will “neck off” at the top of the gap 460. In this way each channel 507 is filled with a vacuum space 510. Such a gap fill 409, 510 would have low thermal conductivity.

The presence of a vacuum in the region of the created gap, 413, can be important to various embodiments of the device type. In addition, the presence of a PECVD Film, 430 can form the environment of the gap 413 in a low vacuum state. However, further processing of the device can allow for molecules to penetrate the PECVD film subverting the vacuum state. At SD, this issue can be resolved by deposition of a metallic film on the outside of all the PECVD insulator films, as shown by items 570 and 571. Films 570-571 can be include, for example deposited Au.

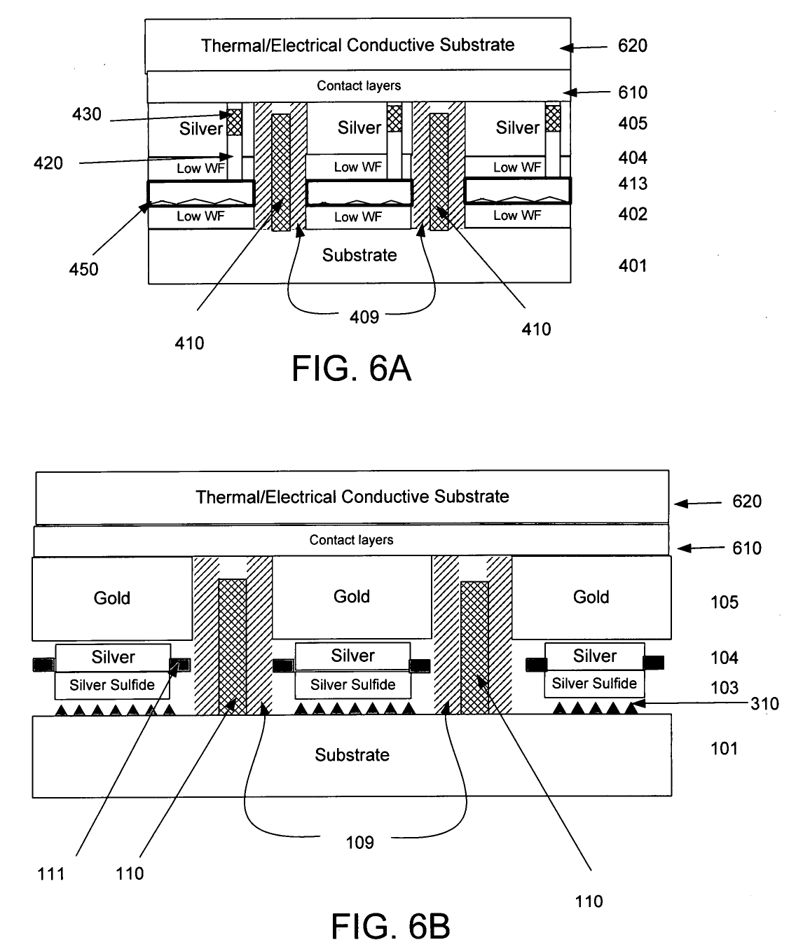

Referring now to FIGS. 6A and 6B, processed embodiments of the two different types are shown in a further completed form. The top films, 105 and 405, for example, can be further processed to include additional layers that can be used to contact the individual features 105 and 405 together. It should be noted that the nature of these connections can be designed for complex regional grids of the individual thermal diode cells or alternatively arrayed in a single contact pattern. The layers 610 can include materials such as, for example: Ti, Ni, and Au that can form a solderable layer to a top substrate material 620.

The present invention can also include application of a DC voltage across the layer of 620 and the layer of 101 or 401 thereby causing the transfer of thermal energy between theses layers. In addition, a temperature differential can be applied across the layer of 620 and the layer of 101 or 401 thereby causing a DC voltage to be generated across these layers.

It is also within the scope of the invention to form a low work function layer, such as, for example: 402, 404 through the processing of a layer of another material. For example, it is within the scope of the invention to apply a layer of metal and expose the metal to a gas to form a low work function layer 402, 404.

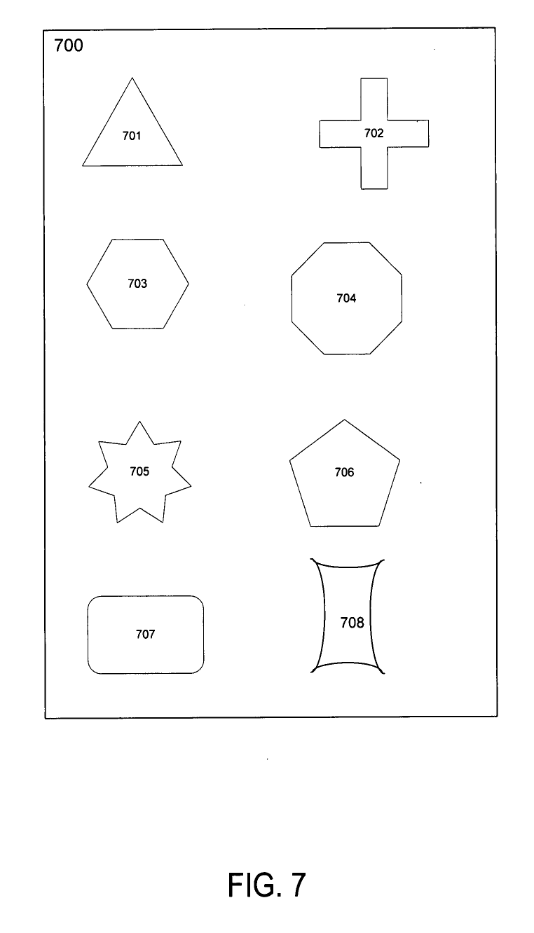

Referring now to FIG. 7, side views have been illustrated in the previous diagrams, a top down view can illustrate that the etched portions 701-708 can be fashioned in numerous designs according to a specific application. Accordingly, various layers 700 can be etched in specific areas which correspond to a particular application and a substrate can be designed or cut into a shape that is suitable for a particular application. Therefore, a substrate and subsequent layers can have thermal transfer areas which correlate to areas for which the thermal energy present is to be controlled in a particular application.

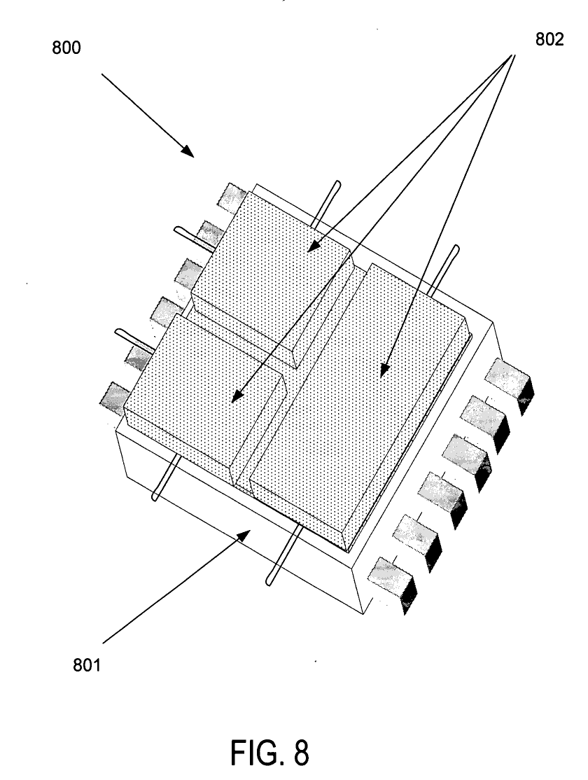

Referring now to FIG. 8, in still other embodiments, it is within the scope of this invention to incorporate the above layers 802 and functionality into the design of an article, such as an integrated circuit chip 801 so that the entire article 800 has an inherent capability to control the thermal energy of specific areas of the chip 801. Generally, it may be advantageous to cool various portions of a chip 801, but some embodiments may include application of the thermal transfer properties of the present invention to create temperature differentials across defined areas or to limit temperature differentials across defined areas. Other embodiments may include transferring thermal energy to or from an area based upon one or more of a defined upper and lower temperature threshold.

Accordingly, it is within the scope of some embodiments of this invention to fashion thermal transferring devices that can identify areas that need to be heated or cooled on an adjacent device. For example, a device can be designed that correlates with hot areas on an integrated circuit chip. Some embodiments therefore, can include, a thermal transfer device that can be used to limit temperature deltas across an integrated circuit, or conversely to drive a temperature delta across an integrated circuit. In addition, a thermal transfer device can be designed, or controlled by a microprocessor, to respond to an upper or lower threshold of temperature across multiple areas and heat or cool individual areas according to a desired result.

It is also within the scope of this invention to fashion composite devices that are formed from combinations of the devices that have been described, or others which fall within the scope of this invention, with each other or with other devices. In particular, for example, a composite device can be formed by the stacking of numerous devices of the type shown in FIG. 6A. The motives for such a composition of individual devices can range, for example, from improving the thermal conduction figures of merits for loss by back diffusion of thermal energy. Finally, such a composite device (not illustrated herein) can have advantages of a most desired temperature gradient that can be supported across the device, since the thermal gradient across each device would be a portion across the composite device.

### CONCLUSION

A number of embodiments of the present invention have been described. Nevertheless, it will be understood that various modifications may be made without departing from the spirit and scope of the invention. For example, various methods or equipment may be used to implement the process steps described herein or to create a device according to the inventive concepts provided above and further described in the claims. In addition, various casings and packaging can also be included in order to better adapt a thermoelectric or thermodiodic device according to a specific application. Accordingly, other embodiments are within the scope of the following claims.

What is claimed is:

1. A device with a first surface and a second surface comprising thermo diodic characteristics between said first surface and said second surface, and further comprising:
a substrate with a metallic surface;
a first metallic layer comprising a different metal than the metallic surface of the substrate, said first metallic layer in electrical contact with the metallic surface of the substrate;
an conductive ionic layer in electrical contact with the first metallic layer;
a second metallic layer with the conductive ionic layer; and
a third metallic layer, said third metallic layer in electrical contact with the second metallic layer.

2. A device with a first surface and a second surface comprising thermo diodic characteristics between said first surface and said second surface, and further comprising:
a substrate with a metallic surface;
a first metallic layer comprising a different metal than the metallic surface of the substrate, said first metallic layer in electrical contact with the metallic surface of the substrate;
a conductive ionic layer in electrical contact with the first metallic layer; and
a second metallic layer, said second metallic layer separated from the conductive ionic layer by a gap which thermally insulates the second metallic layer from the conductive ionic layer.

3. The device of claim 2 wherein the gap comprises a low pressure ambient sufficient to provide thermal insulation between the second metallic layer and the conductive ionic layer.

4. The device of claim 2 wherein a DC current can be applied across the first surface and the second surface to transfer thermal energy through the device.

5. The device of claim 2 wherein a temperature differential can be applied across the first surface and the second surface to cause a voltage to be generated.

6. The device of claim 1 wherein: the first metallic layer and second metallic layer comprise silver, the conductive ionic layer comprises silver sulfide; and the third metallic layer comprises gold.

7. The device of claim 2 wherein: the first metallic layer comprises silver, the conductive ionic layer comprises silver sulfide; and the second metallic layer comprises gold.

8. The device of claim 1 wherein the conductive ionic layer comprises a first surface in electrical and thermal contact with the first metallic layer and a second surface, wherein the second surface comprises an atomically textured area.

9. The device of claim 1 wherein the conductive ionic layer comprises a first surface in electrical and thermal contact with the first metallic layer and a second surface in electrical and thermal contact with the second metallic layer and each of the first surface and the second surface comprises an atomically smooth area.

10. The device of claim 1 wherein the first metallic layer and second metallic layer comprise silver; the conductive ionic layer comprises silver sulfide and the third metallic layer primarily comprises gold and the device additionally comprises at least one intervening gap layer between the gold and the metallic substrate surface.

11. The devices of claim 10 additionally comprising a layer of spin on glass.

12. A device with a first surface and a second surface comprising thermo diodic characteristics between said first surface and said second surface, and further comprising:
a substrate with a metallic surface;
a first layer of low work function metal comprising a different metal than the metallic surface of the substrate, said first low work function metal layer in electrical contact with the metallic surface of the substrate;
a sacrificial layer of selectively etchable material in physical contact with the first low work function metal layer;
a second low work function metal layer, said second low work function metal layer in contact with the second layer of low work function metal; and
a third metallic layer in contact with the second low work function metal layer.

13. The device of claim 12 additionally comprising a contact via formed through the second low work function metal.

14. The device of claim 13 wherein the a sacrificial layer of selectively etchable material is replaced by a gap which thermally insulates the first low work function layer from the second low work function layer.

15. The device of claim 14 wherein the contact via is sealed.

16. A thermo transfer device with a first surface and a second surface wherein the first surface comprises multiple areas and the application of a direct current voltage can be applied to individually cause the transfer of thermal energy from the specified area of the first surface to the second surface.

17. The thermo transfer device of claim 16 wherein at least one of the multiple areas comprising the first surface corresponds with an area on an adjacent article and the direct current voltage can be applied to the at least one multiple area to transfer thermal energy away from the area on the adjacent article.

18. The thermo transfer device of claim 17 wherein a temperature threshold has been designated for the area on the adjacent article and the direct current voltage is applied based upon the temperature of the area on the adjacent article relative to the temperature threshold.

19. The thermo transfer device of claim 18 wherein the thermo transfer device and the adjacent article comprise a composite discrete device.

20. A device with a first surface and a second surface comprising thermo diodic characteristics between said first surface and said second surface, and further comprising:
a substrate with a metallic surface;
a first metallic layer comprising an atomically textured metal, said first metallic layer in physical contact with the metallic surface of the substrate;
a conductive ionic layer, said conductive ionic layer separated from the first metallic layer by a gap which thermally insulates the first metallic layer from the conductive ionic layer; and
a second metallic layer, said second metallic layer in physical contact with the conductive ionic layer.

21. The device of claim 20 wherein the textured metal comprises spikes generated via ionic migration through the ionic conductor induced by an electrical current.

22. The device of claim 21 furthered processed with etching through a contact via.

23. The device of claim 22 additionally comprising a sealant which seals the gap in a vacuum state sufficiently void of molecules to reduce thermal parasitics between the second metallic layer and the conductive ionic layer.

24. A device with a first surface and a second surface comprising thermal diodic characteristics between said first surface and said second surface, and further comprising:
two or more stacked portions wherein each portion comprises thermal diodic characteristics and each portion further comprises:
a substrate with a metallic surface;
a first metallic layer comprising an atomically textured metal, said first metallic layer in physical contact with the metallic surface of the substrate;
a conductive ionic layer, said conductive ionic layer separated from the first metallic layer by a gap which thermally insulates the first metallic layer from the conductive ionic layer; and
a second metallic layer, said second metallic layer in physical contact with the conductive ionic layer.

25. The device of claim 24 wherein an electrical current can be applied between the substrate and the second metallic layer of any respective portion to cause a transfer of thermal energy between the substrate and the second metallic surface.
